(19) United States
(12) Patent Application Publication
(10) Pub. No.: US 2011/0244675 A1
(43) Pub. Date: Oct. 6, 2011

(54) Structure and method of forming pillar bumps with controllable shape and size

(75) Inventors: Jung-Tang Huang, Taipei (TW); Hou-Jun Hsu, Taipei (TW)

(73) Assignee: Jung-Tang Huang

(21) Appl. No.: 12/928,548

(22) Filed: Dec. 15, 2010

(30) Foreign Application Priority Data
Apr. 1, 2010 (TW) 099110034

(51) Int. Cl. H01L 21/441

(52) U.S. Cl. 438/614; 257/E21.477

(57) ABSTRACT

A structure and method of forming pillar bumps with controllable shape and size are provided, which use polishing planarization technology to eliminate shape difference among pillar bumps on a wafer and die, thus yield the pillar bumps with design shape and size.

### FIELD OF INVENTION

This invention relates to the method of formation and structure of pillar bumps with shape and size controllable, it specifically relates to a technique that uses polishing and planarization technique to let all pillar bumps have size and shape matching the design.

### DESCRIPTION OF RELATED ART

As wafer level package technology keeps improve, the utilization of wafer level package has become more popular. In traditional wafer design, it includes many same chip units, hence, the pads and bumps corresponding to packaging have the same size. However, in order to reduce the manufacturing cost, different chips are considered to be designed on the same wafer, for example, system on a chip (SOC). Therefore, size of pads and bumps corresponding to packaging will then have change, moreover, the shape of each bump and the arrangement between bumps can be changed based on the functional requirement, moreover, the losses caused by the necessary connection to other devices, including the current-resistance capability in the power supply network, the insertion loss or impedance match in high frequency communication network, the signal delay in high speed data transmission network, etc. can be reduced to its minimum. However, to cope with functional requirement, the pad and bump size might not only be different, but might also be very different. When conductive bump is formed using electroplating way on the wafer, due to different bump size, even under the same electroplating condition, the same electroplating quantity will form lower height on the conductive bump with larger size. Based on the above statement, bumps of different heights will then be formed on the wafer. When it is connected to the substrate, lower bump on the wafer will be limited by higher bump, hence, good connections might not be formed on some bumps, and the yield is reduced in turn, hence, the final goal of cost reduction can not be achieved eventually.

In order to improve the yield reduction due to coplanarity, please refer to US patent: U.S. Pat. No. 6,416,386 B2, U.S. Pat. No. 6,348,401 B1, U.S. Pat. No. 6,975,016 B2, U.S. Pat. No. 6,975,127 B2, U.S. Pat. No. 766,708 B2 and patent of Republic of China: TW 583729 B, TW 253157 B, TW 280643 B, TW 299204 B. To sum up the results, we see that pressing method or two-stage deposition method is used to improve the coplanarity. However, although the use of direct pressing of bump can make the bump reach certain degree of coplanarity, yet the bump shape, size or even the substrate is compressed, damage on the bump itself or the substrate might be possible, which might in turn causes some changes on the electrical or heat-dissipating related characteristics, that is, it might be quite different than the bump performance simulation and design before packaging, eventually, the reliability and quality of the electronic device before and after packaging might be greatly reduced. In addition, although the height is consistent after compression, yet the width is still not consistent, some are fat and some are thin, that is, for high frequency communication and high speed transmission, inconsistent impedance will be caused, and the transmission quality might be affected. However, the use of two-stage deposition method is even time-consuming and tedious, and the processing cost is in turn greatly increased. Furthermore, all the above methods can not adapt to the current semiconductor process with critical dimension smaller than 28 nm and I/O number larger than 10,000 per cm², and the solder bump preparation requirement when the pitch is smaller than 100 μm.

Refer to patent TW 463271 B of the Republic of China, “Method and device for control the height of wafer level flip-chip bump”. The patent is the control method of the flip chip bump as proposed by the inventor of the present invention. Its main content is to specify the use of Chemical Mechanical Polishing (CMP) or a process similar to mechanical polishing. That is, to study the influence on the bump height control for single layer electroplating of different metal or alloy and different types polishing slurry. Through the verification of the patent, it is proved that mechanical or chemical polishing process can effectively control the flip chip bump height after electroplating to within certain coplanarity.

From a study and forecast of research institute ITRS, the solder balls used in the current flip chip packaging technology, when the pitch becomes smaller and smaller, is going to face with many new problems, for example: (1) The electrode reliability under high density, (2) Heat trap or thermal runaway effects caused by thermal dissipation capability, (3) When I/O becomes more in unit area of silicon device, the pitch between bumps is going to become closer; all these issues are going to show up one after another after the miniaturization of IC, and the use of pillar bump is going to reduce these issues to the smallest extent. Therefore, pillar bump is going to gradually replace the use of solder bump in flip chip packaging and wafer level package.

In the coplanarity control of pillar bumps, the traditional pressing method or two-stage deposition method even has no room for existence, hence, polishing planarization is going to be the only feasible method, which is especially true in the preparation of pillar bump of the same height but different size or shape and structure for certain applications.

### SUMMARY

Due to the needs regarding the design of pillar bump of different sizes in wafer level package, the inventor has proposed here a formation method and structure for pillar bumps with same height. Through the use of polishing and planarization method, pillar bump of different size/or shape can be guaranteed to have the same bump height.

Furthermore, in order to prepare pillar bump and structure of the same height but different size or shape, here a formation method for pillar bump with controllable shape is proposed. In the method, it has a combined use of photolithography process, electroplating process and polishing and planarization process, that is, after each layer of structural electroplating, a polishing and planarization process is performed so as to form pillar bump of consistent height but different sizes or shapes.

### BRIEF DESCRIPTION OF DRAWINGS

FIG. 1: It illustrates the process and step of pillar bump of the embodiment of the present invention.

FIG. 2: It illustrates the structural form of pillar bump of the embodiment of the present invention.

FIG. 3: It illustrates the pad shape of the pillar bump of the embodiment of the present invention.

FIG. 4: It illustrates the opening process of the structural layer of the smaller solder tip to be electroplated of the pillar bump of the embodiment of the present invention.

FIG. 5: It illustrates the pillar bump that is compressed and planarization in the embodiment of the present invention.

FIG. 6: It illustrates the pillar bump structure of diffusion barrier layer of the embodiment of the present invention.

The following description should be read with reference to the drawings, in which like elements in different drawings are numbered in like fashion. The drawings, which are not necessarily to scale, depict selected embodiments and are not intended to limit the scope of the invention. Although examples of construction, dimensions, and materials are illustrated for the various elements, those skilled in the art will recognize that many of the examples provided have suitable alternatives that may be utilized.

### DETAILED DESCRIPTION

The main objective of this invention is constructed on the combined application of the processes provided by the suppliers of the current processes, which include photolithography process, electroplating process and polishing and planarization process, etc.

Referring to the attached drawings, a method of formation and structure of pillar bumps with shape and size controllable will be illustrated in detail as follows.

### Embodiment 1

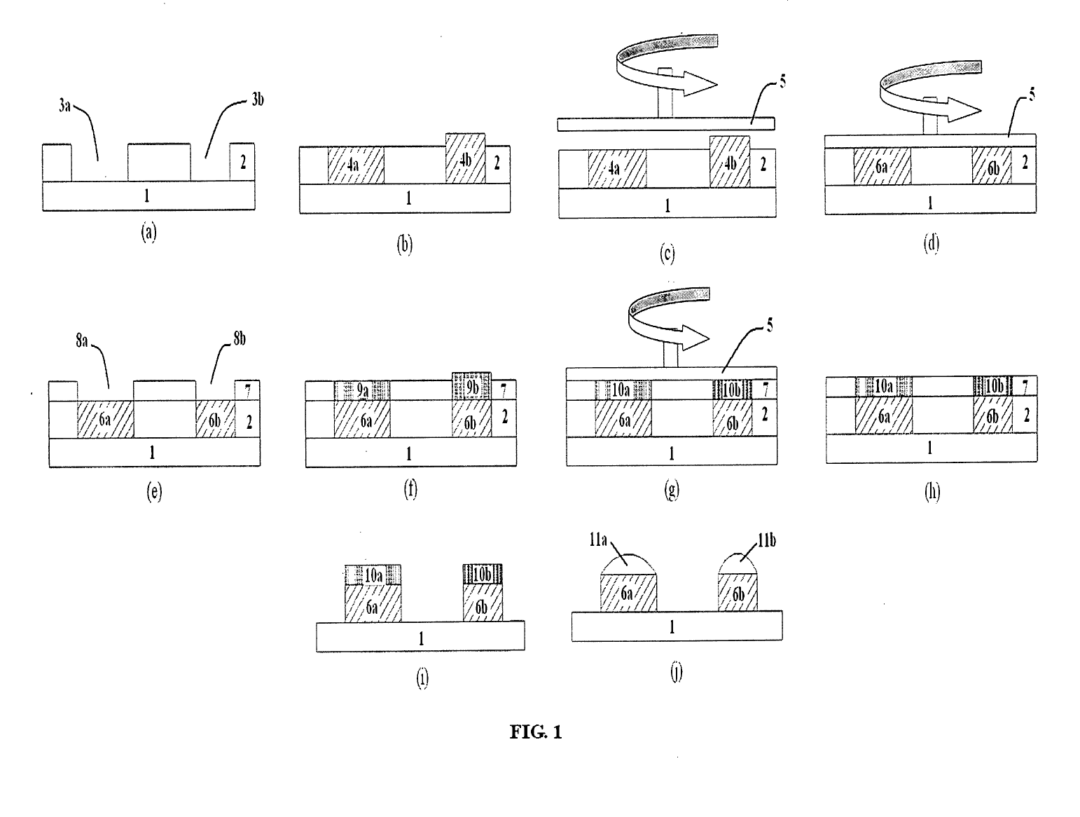

The process and structural part taking place on the wafer substrate surface will be magnified and described; however, it should not be used to limit the scope of the present invention. In addition, in the real wafer surface and method, it can include other necessary part of this structure. FIG. 1 is described in detail as in the following:

Step 1: As shown in FIG. 1(a), first, a first mask layer 2 is covered on wafer substrate 1 (the above structure is omitted here and is not drawn) that is done in advance using appropriate methods for the formation of, for example, some metallic connection pad, insulation protection layer, under bump metallization (UBM); meanwhile, appropriate method is used to remove part of the first mask layer 2 so as to form some opening 3a(first opening) and opening 3b(second opening) of metal pillar structural layer that is to be electroplated, which is located respectively above the metallic pad that is deployed in advance. First mask layer 2 is a photosensitive photo resist, which is covered through attachment method or spin-coating method and is removed through general microlithography or etching way; however, the present invention is not limited to the above ways. Furthermore, the thickness rang of the first mask layer 2 is dependent on the height of the metallic pillar to be formed in the subsequent process. In addition, the opening 3a and opening 3b of the metallic pillar to be electroplated depends on the diameter of the metallic pillar to be formed in subsequent process. In the current embodiment, the width of the opening 3a is larger than that of opening 3b.

Step 2: Referring to FIG. 1 (b), an electrically conductive metal, for example, pure metal such as Cu or Ni or its alloy, is filled respectively to opening 3a and opening 3b so as to form metallic pillars 4a and 4b. In one embodiment, metallic pillar 4a and metallic pillar 4b are performed using electroplating method. What needs to be explained is: since the width of opening 3a is larger than the width of opening 3b, under the same electroplating condition and time, when metallic pillar 4a located at opening 3a is fully filled, the height of metallic pillar 4b filled at opening 3b is going to exceed metallic pillar 4a.

Step 3: Due to the height difference between metallic pillar 4a and 4b after the electroplating process, the yield of subsequent process is going to be affected, hence, here a polishing mechanism 5 is used to planarize it so as to form planarized metallic pillar 6a and 6b, which is as shown in FIG. 1 (c) and FIG. 1 (d). In the current embodiment, the polishing mechanism 5 used can be polishing and planarization mechanisms such as traditional mechanical polishing or advanced chemical and mechanical polishing (CMP).

Step 4: Please refer to FIG. 1 (e)˜FIG. 1 (h) and repeat Step 1˜3. That is, coat a second mask layer 7 on the planarization metallic pillar 6a, 6b and first mask layer 2, then prepare again solder tip structural layer opening 8a, 8b to be electroplated; then electroplating is used again to complete the preparation of solder tip 9a, 9b, similarly, polishing mechanism 5 is used again to planarization it to obtain planarization solder tip 10a and 10b. Here, the material of second mask layer 7 is the same as that of first mask layer 2, that is, they are all photo-resists, moreover, the thickness range of second mask layer 7 depends on the solder tip height to be formed subsequently. In addition, the shape and size of structural layer opening 8a and opening 8b of the solder tip to be electroplated is designed based on the needed electroplating solder volume for obtaining spherical bump height after reflow and through advance design and calculation of solder tip electroplating height for the same volume.

Step 5: Next, first mask layer 2 and second mask layer 7 is to be removed, then the planarization solder tips 10a and 10b are performed with reflow process so as to obtain spherical solder bumps 11a and 11b. Until now, above wafer substrate 1, we can obtain pillar bump structure of the consistent height but different size or shape.

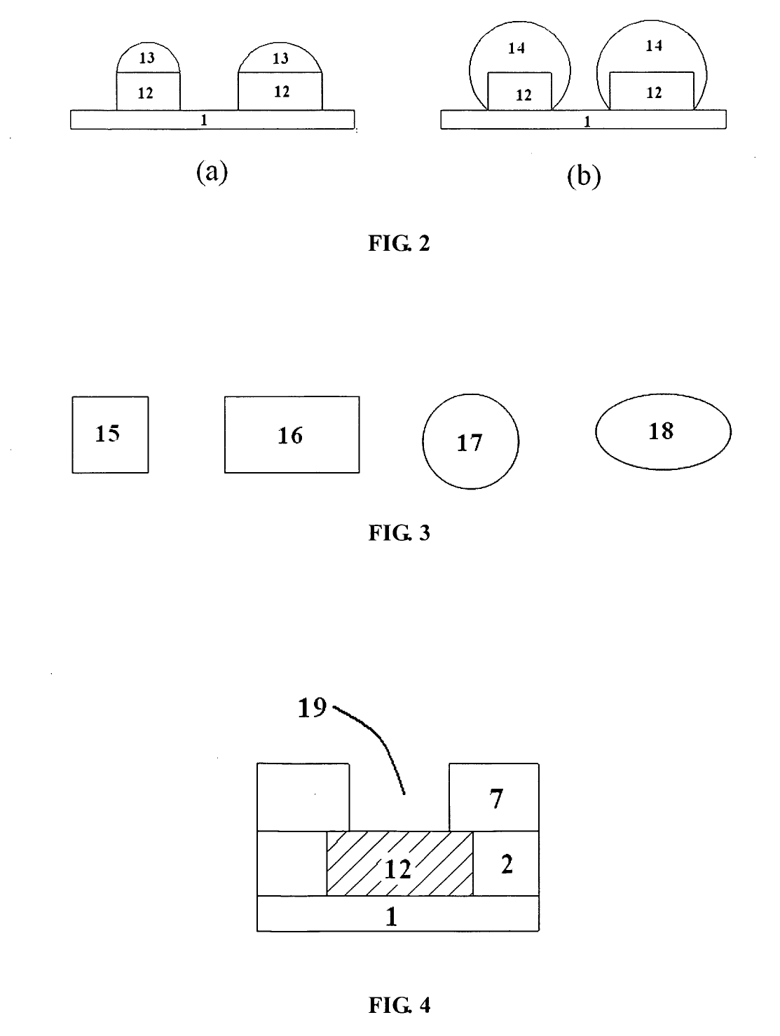

In the current embodiment, the structural form of pillar bump is as in FIG. 2 (a), which is formed by metallic pillar 12 and spherical solder bump 13 after reflow; or it is as shown in FIG. 2 (b), which is formed by metallic pillar 12 and the spherical pad bump 14 coated at the outside of metallic pillar; here, the same size or shape and height of pillar bump is designed according to the real device functional requirement, which is as shown in FIG. 3. Its shape can be square 15, rectangle 16, round 17, oval shape 18, etc., which depends on the real requirement.

During the preparation of solder tip, as shown in FIG. 4, the structural layer opening 19 of the solder tip to be electroplated can be smaller than the original size of metallic pillar 12; only through advance design, we can calculate the electroplating height of the same volume of solder tip, after the reflow, we can also obtain spherical bump of the same shape and height; moreover, the alignment easiness in the preparation of opening 19 of structural layer of solder tip to be electroplated will be enhanced, and the yield will be greatly increased too.

Furthermore, the shape of pillar bump is designed based on the device functional requirement, as shown in the prior art technology, if compression method is used to control the pillar bump height on the same wafer or the same chip as in FIG. 5, although the height can be consistent, yet after the spherical solder bumps 20 and 21 after compression and planarization are all distorted and can not match the expected design and requirement, hence, the original design function can not be achieved, and the packaging yield is thus reduced.

However, the polishing and planarization technique used in this invention does not have such issues, that is, not only the pillar bump height can be accurately controlled, but also the shape and appearance of the completed pillar bump can perfectly match the advance designed one, in other words, product yield is greatly enhanced.

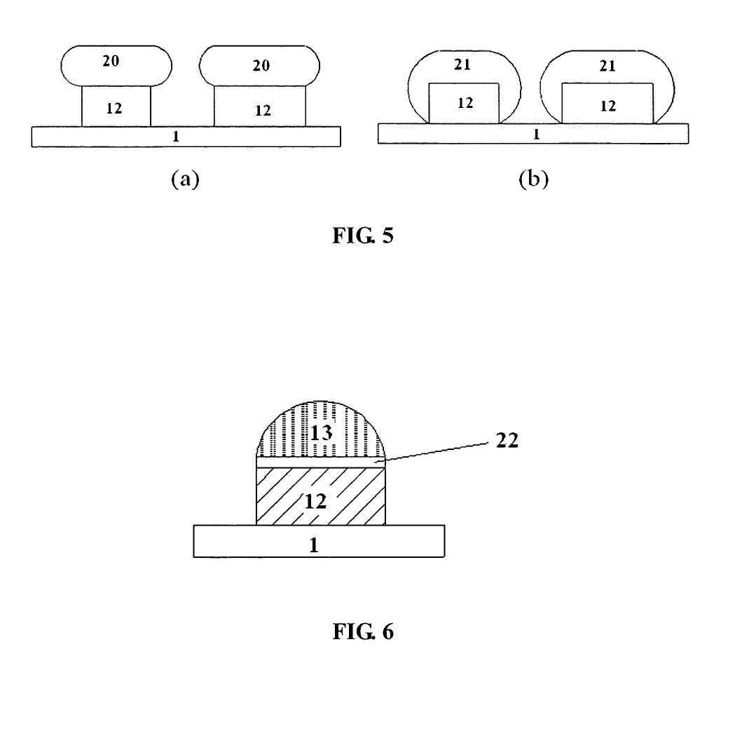

In addition, the pillar bump structure of this invention is as shown in FIG. 6. If the metallic pillar material is Cu, a diffusion barrier layer 22 can be added between metallic pillar 12 and spherical solder bump 13, for example, Ni. Since Ni has slower dissolution rate and slower inter-metallic formation rate in liquid tin as compared to that of Cu, it is thus used to reduce the form and formation rate of inter-metallic and to enhance the adhesion strength of solder tip, hence, the yield and reliability of electronic device is affected indirectly. Although in the above description, the metal layer of metallic pillar is only one or two layers, yet the layer number and material type this invention can be applied to is not limited by this.

To sum up the above statement, we see that the key of the present invention is that the metal layer of metallic pillar is of at least one layer, the material type is not limited, and the shape and size can be designed according to different function. If the function is electrical property, it can be low frequency signal, high frequency signal, RF signal, high and low power signal, power transmission, whether current resistance is needed, or whether lower transmission delay is needed, or the need of impedance match, or high bandwidth and low insertion loss, etc.; if the function belongs to heat dissipation, the key is whether the heat can be dissipated easily or not. That is, on the same wafer or chip, metallic pillar design of different shape and size is allowed. Through the planarization technology of the present invention, we can ensure that metallic pillar of different shape and size can have the same height. Moreover, due to the high accuracy of the prior art microlithography and electroplating technology, the projection face shape and size can be ensured, hence, three dimensions of metallic pillar of different shape and size can follow the design to be accurately controlled. When metallic pillar is controlled, the next is to perform solder tip preparation, here metallic pillar at the bottom with different shape and size can be followed to calculate in advance the future reflowed shape, and the needed solder volume can then be provided; moreover, the realization of the volume is decided through the height of solder tip multiplied by the needed bottom area, and the bottom area is the area of the solder tip opening to be electroplated. The above reflowed shape can be the full enclosure of the metallic pillar by the solder, it can also be the partial enclosure of metallic pillar by the solder, or it can be only the solder bottom connection to the upper layer of the pillar layer. Therefore, the present invention can indeed control pillar bump of different shape and size effectively so that it can meet the design requirement. It includes the simultaneous control of the three dimensional shape and size of metallic pillar, and the three dimensional shape and size of solder tip.

Having thus described the several embodiments of the present invention, those of skill in the art will readily appreciate that other embodiments may be made and used which fall within the scope of the claims attached hereto. Numerous advantages of the invention covered by this document have been set forth in the foregoing description. It will be understood that this disclosure is, in many respects, only illustrative. Changes may be made in details, particularly in matters of shape, size and arrangement of parts without exceeding the scope of the invention.

What is claimed is:

1. A formation method for pillar bump with controllable three dimensional shape and size, comprising of:
providing a wafer substrate with the following structures above it, namely, some metallic interconnection pads, insulation protection layer, under bump metallization (UBM), etc.;
forming a first mask layer on top of wafer substrate;
removing part of the first mask layer so as to form at least one first opening and one second opening of the structural layer of metallic pillar to be electroplated and to expose part of the electrically conductive interconnection structure, wherein the size of the first opening is larger than that of the second opening;
electroplating a first metallic pillar to fill fully the first opening and to fill into the second opening;
using polishing and planarization process to form planarized metallic pillar;
forming a second mask layer above the first mask layer and planarized metallic pillar, and forming the structural layer opening of solder tip to be electroplated; and
filling in and electroplating the structural layer opening of solder tip to be electroplated;
using polishing and planarization process to form planarized solder tip;
removing the first mask layer, the second mask layer and under bump metallization structure; and
performing reflow process so as to obtain spherical solder bump and to eventually obtain pillar bump of equal height.

2. The formation method of claim 1 wherein the structural layer opening of metallic pillar to be electroplated as formed by the first mask layer and the second mask layer and structural layer opening of solder tip to be electroplated are completed by photolithography process.

3. The formation method of claim 2 wherein the first mask layer and the second mask layer are photo-resist, which are either dry films or liquid films.

4. The formation method of claim 1 wherein the step of forming the second mask layer on the first mask layer and planarized metallic pillar is first to cover fully on the first mask layer and planarized metallic pillar, then remove the second mask layer covering the planarized metallic pillar so as to expose the structural layer opening to be electroplated.

5. The formation method of claim 4 wherein the area size of the structural layer opening of solder tip to be electroplated as exposed by the second mask layer is designed according to the solder volume needed by solder tip height after actual reflow.

6. The formation method of claim 1 wherein the mentioned polishing and planarization is through polishing and planarization mechanisms such as mechanical polishing or chemical mechanical polishing (CMP), etc.

7. The formation method of claim 1 wherein the pillar bump structure is a double layer structure formed by a planarized metallic pillar and a planarized solder tip or a reflowed spherical solder bump.

8. The formation method of claim 1 wherein the pillar bump structure is a structure formed by a planarized metallic pillar and a spherical solder bump covered at the outside of metallic pillar.

9. The formation method of claim 1 wherein metallic pillar is composed of at least one layer of material selected from composed group of Cu, Ni, or their metal alloy.

10. The formation method of claim 1 wherein the material of solder bump is either lead-containing or lead-free solder, which depends on the process need.

11. The formation method of claim 1 wherein the pillar bump is pillar bump of different size or shape selected from group composed of square, rectangular, round and oval shape, depending on the actual need.
